(19) United States
(12) Patent Application Publication
(10) Pub. No.: US 2011/0265722 A1
(43) Pub. Date: Nov. 3, 2011

(54) WAFER TRAY FOR CVD DEVICE, HEATING UNIT FOR CVD DEVICE AND CVD DEVICE

(75) Inventor: Toshikazu TAKENAKA, Hannou-shi (JP)

(73) Assignee: SHOWA DENKO K.K., Tokyo (JP)

(21) Appl. No.: 12/971,551

(22) Filed: Dec. 17, 2010

(30) Foreign Application Priority Data
Dec. 21, 2009 (JP) 2009-289520
Jun. 23, 2010 (JP) 2010-142694

(51) Int. Cl. C23C 16/458; C23C 16/46

(52) U.S. Cl. 118/725; 118/728

(57) ABSTRACT

The present invention provides a wafer tray for a CVD device, heating unit for a CVD device provided with the wafer tray for a CVD device, and a CVD device provided with the wafer tray for a CVD device that includes a wafer tray main body provided with cavities enabling mounting of a wafer on a first surface, and a connection portion formed to project towards a second surface of the wafer tray main body. A connection indented portion is provided in the connection portion to enable detachable connection to the rotation shaft that enables rotation of the wafer tray main body.

### TECHNICAL FIELD

The present invention relates a wafer tray for a CVD device, a heating unit for a CVD device, and a CVD device.

The present application claims the benefit of Japanese Patent Application 2009-289520 filed in Japan on Dec. 21, 2009 and Japanese Patent Application 2010-142694 filed in Japan on Jun. 23, 2010, the entire disclosure of which is incorporated by reference herein.

### BACKGROUND ART

A chemical vapor deposition (CVD) method is known as a technique for forming a thin semiconductor film on a substrate in a manufacturing process for a semiconductor device. In a CVD method, the thin film is formed by producing a chemical reaction on a wafer by bringing the wafer that is heated to a reaction temperature into contact with a reaction gas.

Generally, the heating unit that is used when forming the thin film by this type of CVD method has the configuration described below. FIG. 9 is a sectional view showing an example of a heating unit 21 for a conventional CVD device.

As shown in FIG. 9, the conventional heating unit 21 is substantially configured by a wafer tray 22 for a CVD device, a heater 23, a heat shield 24, a heat shield ring 25, and a rotation shaft 26.

The wafer tray 22 is configured with a predetermined thickness in a disk shape when viewed in plan. A plurality of cavities 27 enabling mounting of wafers is provided on a first surface 22a.

A connection indented portion 28 that enables detachable connection of the rotation shaft 26 is provided in substantially the center of a second surface 22b of the wafer tray 22. In FIG. 9, the bottom portion 28b of the connection indented portion 28 has a smaller diameter than the opening 28a, and is formed in a bowl shape.

The heater 23 is disposed toward the other side 22b of the wafer tray 22 and is separated from the wafer tray 22 by a predetermined distance. Tungsten or the like is known as a material for the heater 23.

In FIG. 9, the heat shield 24 is disposed on a lower side of the heater 23. The heat shield 24 is provided to prevent heat produced by the heater 23 from escaping downwardly.

The heat shield ring 25 is provided to enclose the outer periphery of the heater 23 and the heat shield 24. The heat shield ring 25 is provided to prevent heat from the heater 23 from escaping sidewards.

The rotation shaft 26 is provided to rotate the wafer tray 22. A distal end 26a of the rotation shaft 26 is connected to be detachably connected with the connection indented portion 28 of the wafer tray 22. In FIG. 9, the distal end 26a of the rotation shaft 26 is formed as a circular truncated cone with a shape that corresponds to the connection indented portion 28.

The rotation shaft 26 and the wafer tray 22 are not fixed and connected by a special fixing means, but rather are connected by fitting the distal end 26a of the rotation shaft 26 into the indented portion 28. In other words, connection is enabled by the weight of the wafer tray 22.

The rotation shaft 26 is rotatably formed by a suitable rotation means such as a motor or the like (not shown).

When forming a thin film on the wafer by use of a CVD device heating unit 21 having the structure described above, firstly, the wafer is mounted in a cavity 27 of the wafer tray 22, and the wafer tray 22 is displaced by a suitable displacement means so that the distal end 26a of the rotation shaft 26 is fitted into the indented portion 28. The wafer tray 22 is rotated by a rotation shaft 26, and heated by a heater 23.

In the above manner, the wafer is heated to a reaction temperature.

### CITATION LIST

### Patent Literature

[Patent Literature 1] National Publication of International Patent Application No. 2004-525056

### DISCLOSURE OF THE INVENTION

### Problem To Be Solved By the Invention

However in the conventional CVD device heating unit 21, wafer properties are affected by the large temperature distribution of the wafer tray 22, and therefore the problem arises that cracking is produced in the wafer tray 22.

More specifically, since the rotation shaft 26 is connected with a rotation means such as a motor or the like that is disposed in an external section of the CVD device heating unit 21, the rotation shaft 26 has a low temperature in comparison with the wafer tray 22. In addition, the rotation shaft 26 may be cooled by a suitable cooling means such as water cooling, or the like.

As a result, the wafer tray 22 is such that the portion in proximity to the connection indented portion 28 that is in contact with the rotation shaft 26 tends to have a lower temperature than other portions.

In this manner, wafer properties are adversely affected since the temperature of the portion of the wafer towards the center of the wafer tray 22 is lower than the temperature of a portion towards the edge of the wafer tray 22. Furthermore, cracks are produced since the temperature distribution of the wafer tray 22 itself is also large.

The present invention is proposed in light of the above circumstances, and has the object of providing a wafer tray for a CVD device, a heating unit for a CVD device, and a CVD device that exhibit a more uniform temperature distribution.

### Means for Solving the Problem

The present invention is configured as described hereafter.

(1) A wafer tray for a CVD device includes a wafer tray main body provided with cavities enabling mounting of a wafer on a first surface, and a connection portion formed to project towards a second surface of the wafer tray main body. A connection indented portion is provided in the connection portion to enable detachable connection to the rotation shaft that enables rotation of the wafer tray main body.

(2) The wafer tray in (1) above characterized in that the thickness of the wafer tray main body in a portion not provided with the connection portion is less than the depth of the connection indented portion.

(3) The wafer tray in (1) or (2) above characterized in that the thickness of the wafer tray main body in the connection indented portion is at least 50% of the thickness of the wafer tray main body in the portion not provided with the connection portion.

(4) The wafer tray in any one of (1) to (3) above characterized in that the thickness of the wafer tray main body in the connection indented portion is at least 3 mm.

(5) The wafer tray in any one of (1) to (4) above characterized in that a flange is provided on the peripheral edge of the second surface of the wafer tray main body.

(6) The wafer tray in any one of (1) to (5) above characterized in that an indented portion or projecting portion is provided on the second surface of the wafer tray main body.

(7) The wafer tray in (6) above that is characterized in that the indented portion or the projecting portion is configured in a concentric circular shape, radial shape, concentric polygonal shape, a lattice shape, or a spiral shape.

(8) The wafer tray in (6) or (7) above that is characterized in that the indented portion or the projecting portion is configured continuously or non-continuously.

(9) The wafer tray in any one of (6) to (8) above that is characterized in that sectional shape of the indented portion or the projecting portion includes at least one shape selected from the group consisting of a triangular shape, a polygonal shape, or a semicircular arc.

(10) A CVD device heating unit that is characterized by including the wafer tray in any one of (1) to (9) above, a heater that heats the CVD device wafer tray from the second surface side of the wafer tray main body, a heat shield that is disposed on the opposite side to the wafer tray main body with reference to the heater, a heat shield ring that encloses the outer periphery of the heater, and a rotation shaft that enables the wafer tray main body to rotate.

(11) A CVD device provided with the CVD device wafer tray in any one of (1) to (9) above.

### Effects of the Invention

The CVD device wafer tray according to the present invention includes a connection indented portion that enables detachable connection of the rotation shaft to the connection portion that is formed to project from the wafer tray main body. In this manner, the connection portion that is provided with a connection indented portion connected with the rotation shaft is configured to project in contrast to the conventional configuration, and therefore receives radiant heat from the heater.

As a result, the portion in proximity to the connection indented portion that is connected to the rotation shaft of the wafer tray main body is more easily heated than the conventional configuration. Consequently even when a cooling process (thermal conduction) is applied to the rotation shaft, the temperature distribution of the CVD device wafer tray becomes uniform.

The wafer tray main body of the CVD device wafer tray according to the present invention has a thickness that is less than the depth of the connection indented portion. Since the conventional connection indented portion is provided directly on the wafer tray, the thickness of the wafer tray was necessarily greater than or equal to the depth of the connection indented portion. However, the above configuration is enabled since the CVD device wafer tray according to the present invention includes a connection indented portion on the connection portion formed to project from the wafer tray main body.

In this manner, the thickness of the wafer tray main body can be less than the conventional configuration, and thereby reduces the heat capacity of the CVD device wafer tray. As a result, a temperature increase and decrease of at least 100° C./min is enabled in the CVD device wafer tray, and thereby enables a reduction in the manufacturing time required to form the wafer thin film. Furthermore, since the thickness of the wafer tray main body is reduced in comparison to the conventional configuration, weight can be reduced and the load on conveyance equipment or the like can be reduced.

The thickness of the wafer tray main body in the connection indented portion of the CVD device wafer tray according to the present invention is configured to be at least 50% of the thickness of the wafer tray main body in a portion not provided with the connection portion. The CVD device wafer tray according to the present invention is provided with a connection indented portion on the connection portion that is formed to project from the wafer tray main body. Therefore, even when the thickness of the wafer tray main body in the connection indented portion is increased, the heat capacity of the CVD device wafer tray can be reduced.

In this manner, since the wafer tray main body in the connection indented portion has a sufficient thickness, even when a cooling process (thermal conduction) is applied to the rotation shaft, an effect that reaches to the first surface of the wafer tray main body can be prevented, and therefore the mechanical strength of the wafer tray main body can be improved. In particular, the center of gravity of the CVD device wafer tray can be positioned in the wafer tray main body since the thickness of the wafer tray main body in the connection indented portion is at least 50% of the thickness of the wafer tray main body in a portion not provided with the connection portion, and therefore mechanical strength is further improved.

The CVD device wafer tray according to the present invention is configured with a thickness in the wafer tray main body in the connection indented portion of at least 3 mm.

In this manner, cold air about the rotation shaft can be prevented from having a direct effect that reaches the first surface of the wafer tray main body, and consequently, the mechanical strength of the wafer tray main body is improved.

The CVD device wafer tray according to the present invention includes a flange that is provided on a peripheral edge on the second surface of the wafer tray main body. In this manner, radiant heat from the heater, and heat that is reflected by the heat shield can be prevented from escaping in a sideward direction of the heater. Furthermore, radiant heat from the heater can be prevented from leaking from between the CVD device wafer tray and the heat shield ring. As a result, there is no effect for example, on a radiation thermometer that measures the temperature of a first surface of the wafer tray main body, and errors in the measured temperature can be reduced. Furthermore, a temperature reduction in the outer peripheral portion of the CVD device wafer tray can be prevented to thereby enable temperature uniformity.

In an example of a CVD device wafer tray according to the present invention, an indented portion or a projecting portion is formed on a second surface (surface on the heater side) of the wafer tray main body. In this manner, the wafer tray main body can efficiently absorb heat from the heater.

### BRIEF DESCRIPTION OF THE DRAWINGS

FIG. 1 is an example of a sectional view showing a CVD device heating unit according to a first embodiment.

FIG. 2 is an example of a plan view showing a CVD device wafer tray according to the first embodiment.

FIG. 3 is a sectional view along the line A-A′ in FIG. 2.

FIG. 4 is an enlarged view of a portion of FIG. 3.

FIG. 5 is a sectional view along the line B-B′ in FIG. 2.

FIG. 6 is an example of a plan view of a heater according to the first embodiment.

FIG. 7A is an example of a sectional view showing a CVD device wafer tray according to a second embodiment.

FIG. 7B is an enlarged view of a portion of FIG. 7A.

FIG. 8 is a graph showing the temperature at respective distances from the center of a first surface of the wafer tray main body.

FIG. 9 is a sectional view showing a conventional example of the CVD device heating unit.

FIG. 10A illustrates a pattern of disposition of a plurality of indented portions or projecting portions 15 in a concentric orientation.

FIG. 10B illustrates the same pattern of FIG. 10A of disposition of a plurality of indented portions or projecting portions 15 in a concentric orientation, and illustrates a pattern in which each indented portion or projecting portion 15 is separated by a non-configured portion 16 that extends radially from the center of the wafer tray main body 14.

FIG. 10C illustrates a configuration in which the non-configured portion 16 shown in FIG. 10B is formed into concentric sectors.

FIG. 10D illustrates the same pattern as FIG. 10A of disposition of a plurality of indented portions or projecting portions 15 in a concentric orientation, and illustrates a pattern in which the indented portions or projecting portions 15 are configured in a meandering shape.

FIG. 10E illustrates the same pattern as FIG. 10D of disposition of a plurality of indented portions or projecting portions 15 in a meandering shape, and illustrates a pattern in which each indented portion or projecting portion 15 is separated by a non-configured portion 16 that extends as concentric sectors.

FIG. 10F illustrates a pattern in which a plurality of indented portions or projecting portions 15 is disposed radially from the center of the wafer tray main body 14.

FIG. 10G illustrates a pattern in which the indented portion or projecting portion 15 is disposed radially in the same manner as FIG. 10F, and shows a pattern in which the indented portion or projecting portion 15 has a meandering shape.

FIG. 10H illustrates a pattern in which a plurality of indented portions or projecting portions 15 is disposed in a concentric polygonal orientation.

FIG. 10I illustrates a pattern in which the indented portion or projecting portion 15 is disposed only in proximity to the apex of each polygon in FIG. 10H, and other portions are configured as concentric non-configured portions 16.

FIG. 10J illustrates a pattern in which the indented portion or projecting portion 15 is disposed at a position corresponding to a portion of each edge of each polygon in FIG. 10I.

FIG. 10K illustrates a pattern showing the same disposition as FIG. 10H, and in which the indented portion or projecting portion 15 has a meandering shape.

FIG. 10L illustrates a pattern in which the indented portion or projecting portion 15 of a portion corresponding to an edge on a portion of each polygon in FIG. 10H has a meandering shape.

FIG. 10M illustrates a pattern in which a plurality of indented portions or projecting portions 15 is configured as a lattice.

FIG. 10N illustrates a pattern in which a plurality of indented portions or projecting portions 15 is configured as a vortex.

FIG. 11A illustrates a pattern in which a sectional shape of the indented portion 15 is triangular, and the deepest portion 15a of the indented portion is configured with an acute angle.

FIG. 11B illustrates a pattern in which a sectional shape of the indented portion 15 is triangular, and the deepest portion 15a of the indented portion is configured with an acute angle in the same manner as FIG. 11A, and illustrates a pattern in which indented portions 15 of different depths are alternately disposed from an inner side to an outer side.

FIG. 11C illustrates a pattern in which a sectional shape of the indented portion 15 is triangular, and the deepest portion 15a of a groove is configured with a curved surface.

FIG. 11D illustrates a pattern in which a sectional shape of the indented portion 15 is triangular, and the interface portion 15b between the indented portion 15 and the second surface 14b of the wafer tray main body 14 is configured with a curved surface.

FIG. 11E illustrates a pattern in which a sectional shape of the groove 15 is quadrilateral.

FIG. 11F illustrates a pattern in which a sectional shape of the groove 15 is polygonal.

FIG. 11G illustrates a pattern in which a bottom portion of the groove 15 in FIG. 11E forms a spherical recess.

FIG. 11H illustrates a pattern in which a sectional shape of the projecting portion 15 is triangular, and the apex 15c of the projecting portion 15 is configured with an acute angle.

FIG. 11I illustrates a pattern in which a sectional shape of the projecting portion 15 is triangular, and projecting portions 15 of different sizes are alternately disposed.

FIG. 11J illustrates a pattern in which a sectional shape of the projecting portion 15 is triangular, and the apex 15c of the projecting portion 15 is configured with a curved surface.

FIG. 11K illustrates a pattern in which the sectional shape of the projecting portion 15 is polygonal.

FIG. 11L illustrates a pattern in which a spherical protrusion is formed on a portion of the apex of the projecting portion 15.

### BEST MODES FOR CARRYING OUT THE INVENTION

A wafer tray for a CVD device and a heating unit for a CVD device according to an embodiment of the present invention will be described in detail hereafter making reference to the figures.

### First Embodiment

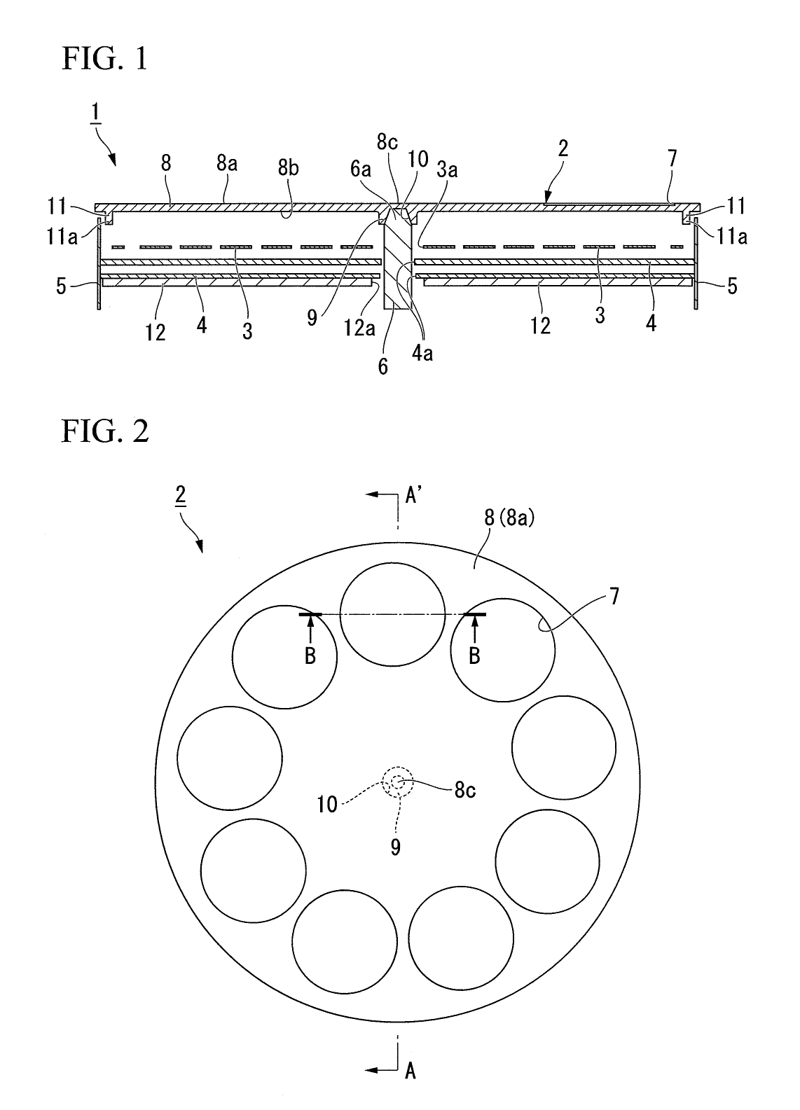

As shown in FIG. 1, a heating unit 1 for a CVD device according to this embodiment is schematically configured from a CVD device wafer tray 2, a heater 3 that heats the CVD device wafer tray 2, a heat shield 4, a heat shield ring 5, and a rotation shaft 6.

[CVD Device Wafer Tray]

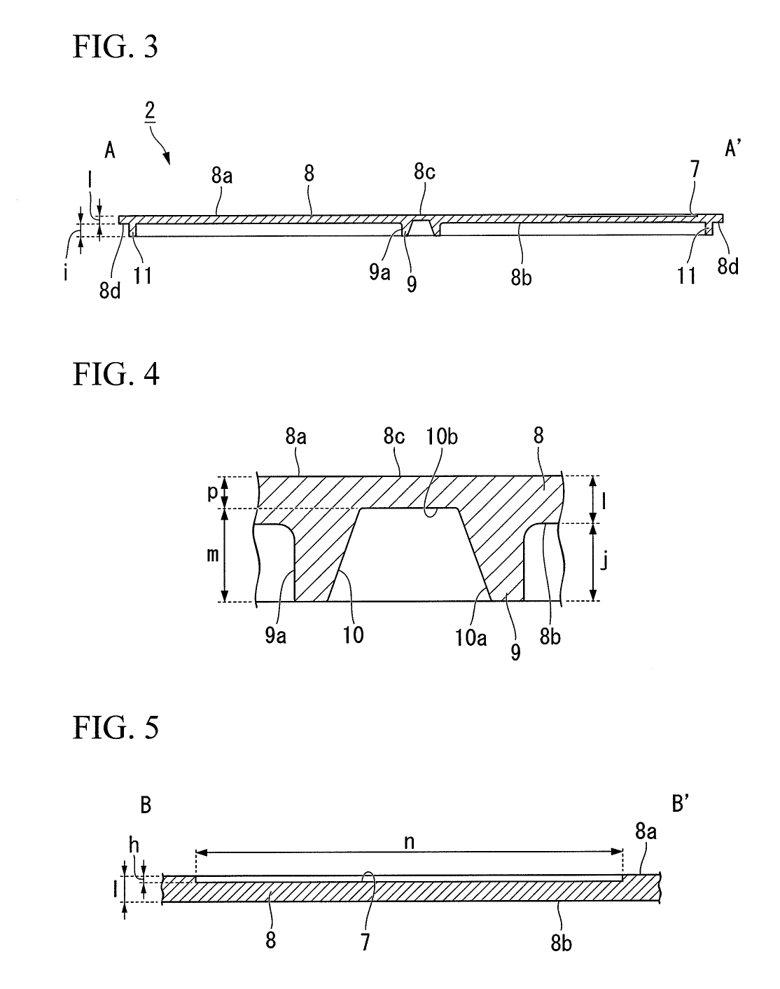

Firstly, the CVD device wafer tray 2 will be described. As shown in FIG. 2 to FIG. 5, the CVD device wafer tray 2 is schematically configured from a wafer tray main body 8 provided with a cavity 7 on one face 8a to thereby enable mounting wafers, and a connection portion 9 projecting towards a second face 8b of the wafer tray main body 8.

The material used in the CVD device wafer tray 2 is preferably black lead, or a black-lead composite material.

The wafer tray main body 8 is configured in a disk shape that is substantially circular when viewed in plan. The thickness l of the wafer tray main body 8 (the thickness at a portion not provided with the connection portion 9, and the thickness in a region in which the cavity 7 is not provided) may take any thickness value, however a value than is smaller than the depth m of the connection indented portion 10 described below is preferred. Furthermore, the thickness l of the wafer tray main body 8 is preferably configured with a low value in view of thermal conduction properties, and for example, may be a thickness of at least 5 mm to no more than 10 mm. When the thickness l of the wafer tray main body 8 is less than 5 mm, the mechanical strength of the main body may be affected due to the formation of the connection indented portion 10 as described below. Furthermore, when the thickness l of the wafer tray main body 8 exceeds 10 mm, there is a risk of an adverse effect on the thermal conductivity behavior in relation to heating/cooling processes (processes to increase or decrease temperature).

A protective layer may be formed on a surface of the wafer tray main body 8. The protective layer is formed by coating at least one type of protective layer material using a CVD process. The protective layer material includes TaC, TiC, NbC, SiC, PBN, diamond, TiN, SiN, AlN. The thickness of the protective layer is preferably 100 μm.

The wafer tray main body 8 may be formed 100% by the protective layer material.

A plurality of identical cavities 7 is provided on the first surface 8a of the wafer tray main body 8 separated from the center 8c by a predetermined distance (In FIG. 2, nine cavities 7 are provided). However, only one cavity 7 may be provided, and the shape of each cavity 7 may be the same or different.

The cavity 7 is formed as a round indentation having a diameter n in plan view that is provided on the first surface 8a of the wafer tray main body 8. The height of the cavity 7 is configured to be less than the thickness l of the wafer tray main body 8. The shape of the cavity 7 is not limited to the size or the shape described above, and may take any shape that enables mounting of a desired wafer.

A flange 11 is provided on a peripheral edge 8d of the second surface 8b of the wafer tray main body 8. The flange 11 is provided at a height i in a substantially vertical orientation with respect to the second surface 8b of the wafer tray main body 8, and is provided along the entire periphery on the peripheral edge 8d of the second surface 8b of the wafer tray main body 8. In other words, the flange 11 is provided in a ring shape when viewed from the side facing the second surface 8b of the wafer tray main body 8.

A connection portion 9 is provided on the second surface 8b of the wafer tray main body 8. The connection portion 9 is provided in substantially the center of the second surface 8b of the wafer tray main body 8, and is provided in an upright orientation from the second surface 8b to thereby project from the second surface 8b. The height j of the connection portion 9 may be the same as the height i of the flange, or may be smaller or greater than i.

The shape of the connection portion 9 is formed in an upright orientation from the second surface 8b of the wafer tray main body 8, and may take any shape that enables provision of the connection indented portion 10 that enables detachable connection with the rotation shaft 6.

For example, a cylindrical shape, or a prism shape may be used. In addition, the angle of the side surface 9a of the connection portion 9 relative to the wafer tray main body 8 may be acute or obtuse, in addition to being perpendicular.

The connection indented portion 10 that enables detachable connection with the rotation shaft 6 is provided on the connection portion 9. The connection indented portion 10 is formed in a bowl shape having a predetermined depth m and a bottom portion 10b that has a small diameter than the opening 10a in order to correspond to the shape of the distal end 6a of the rotation shaft 6.

The shape of the connection indented portion 10 is not limited to a bowl shape, and may take any shape as long as correspondence with the shape of the distal end 6a of the rotation shaft 6 is enabled.

The depth m of the connection indented portion 10 may be any depth as long as the CVD device wafer tray 2 is supported by only the rotation shaft 6 that is connected to the connection indented portion 10. However it is preferred that the depth is larger than the thickness l of the wafer tray main body 8.

Furthermore, the thickness p of the wafer tray main body 8 in the connection indented portion 10 is at least 50% of the thickness of the wafer tray main body 8.

Furthermore, the thickness p of the wafer tray main body 8 in the connection indented portion 10 is preferably at least 3 mm.

The CVD device wafer tray 2 according to the present embodiment is provided with a connection indented portion 10 that enables detachable connection with the rotation shaft 6 on the connection portion 9 that is formed to project from the wafer tray main body 8. In this manner, the connection portion 9 provided with the connection indented portion 10 that is connected to the rotation shaft 6 is formed to project in contrast to the conventional configuration, and therefore receives radiant heat from the heater.

As a result, application of heat to the portion in proximity to the connection indented portion 10 that is connected to the rotation shaft 6 of the wafer tray main body 8 is facilitated to a greater degree than the original configuration, and even when a cooling process (thermal conduction) is applied to the rotation shaft 6, the temperature distribution of the CVD device wafer tray 2 becomes uniform.

The CVD device wafer tray 2 according to the present embodiment is configured so that the thickness l of the wafer tray main body 8 is smaller than the depth m of the connection indented portion 10. Since the indented portion is directly provided on the wafer tray in the conventional configuration, the thickness of the wafer tray must be at least equal to the depth of the connection indented portion. However in the CVD device wafer tray 2 according to the present embodiment, the above configuration is enabled since the connection indented portion 10 is provided on the connection portion 9 that projects from the wafer tray main body 8.

In this manner, the thickness l of the wafer tray main body 8 is reduced more than the conventional example, and the heat capacity of the CVD device wafer tray 2 can be reduced. As a result, a temperature increase and decrease of at least 100 C°/min in the CVD device wafer tray 2 is enabled, and the manufacturing time for forming the thin film on the wafer can be reduced. Furthermore, since the thickness l of the wafer tray main body 8 can be reduced more than the conventional example, weight can be reduced, and the load on conveyance equipment or the like can be reduced.

The CVD device wafer tray 2 according to the present embodiment is configured so that the thickness p of the wafer tray main body 8 in the connection indented portion 10 is at least 50% of the thickness l of the wafer tray main body 8 in a portion that is not provided with the connection portion 9. The device wafer tray 2 according to the present embodiment is provided with a connection indented portion 10 on the connection portion 9 that projects from the wafer tray main body 8. Therefore even when the thickness p of the wafer tray main body 8 in the connection indented portion 10 is increased in this manner, the heat capacity of the CVD device wafer tray 2 can be reduced.

In this manner, since the thickness p of the wafer tray main body 8 in the connection indented portion 10 is sufficiently thick, even when a cooling process (thermal conduction) is applied to the rotation shaft 6, an effect that reaches the first surface 8a of the wafer tray main body 8 can be prevented. Furthermore, the mechanical strength of the wafer tray main body 8 can be improved. In particular, the center of gravity of the CVD device wafer tray is positioned in the wafer tray main body since the thickness of the wafer tray main body in the connection indention portion is at least 50% of the thickness l of the wafer tray main body 8 in a portion not provided with the connection portion 9, and therefore mechanical strength is further improved.

The wafer tray main body 8 in the connection indented portion 10 in the CVD device wafer tray 2 according to the present embodiment is configured with a thickness p of at least 3 mm.

In this manner, even when a cooling process (thermal conduction) is applied to the rotation shaft 6, an effect that reaches to the first surface 8a of the wafer tray main body 8 can be prevented, and in addition, the mechanical strength of the wafer tray main body 8 is improved.

The CVD device wafer tray 2 according to the present invention includes a flange 11 that is provided on a peripheral edge 8d on the second surface 8b of the wafer tray main body 8. In this manner, radiant heat from the heater 3, and heat that is reflected by the heat shield 4 can be prevented from escaping in a sideward direction of the heater 3. Furthermore, radiant heat from the heater 3 can be prevented from leaking from between the CVD device wafer tray 2 and the heat shield ring 5. As a result, for example, an effect on a radiation thermometer or the like that measures the temperature of the first surface 8a of the wafer tray main body 8 can be avoided, and errors in the measured temperature can be reduced. Furthermore, a temperature reduction in the outer peripheral portion of the CVD device wafer tray 2 can be prevented to thereby enable temperature uniformity.

Since the wafer tray is formed from black lead, the processing characteristics of the wafer tray are improved in comparison to conventionally used materials such as quartz glass, SIC sintered bodies, or related CVD formed products, and formation in an superior configuration is enabled. Furthermore, the heating efficiency of black lead is high in comparison to conventional materials.

### [Heater]

Next, the heater 3 will be described. As shown in FIG. 1, the heater 3 that heats the CVD device wafer tray 2 is separated by a predetermined distance from the wafer tray main body 8 on the second surface 8b of the wafer tray main body 8.

Any known material may be used in the heater 3, and for example, tungsten, and the like may be used. The heater 3 is fixed by support from below with a supporting column or the like (not shown).

Although the heater 3 may be formed as a disc, as shown in FIG. 6, a flat shape may be used in which a plurality of band-shaped elements having a predetermined width (two in FIG. 6) are folded in an appropriate manner. The heater 3 may be configured so that the electrodes (not shown) are placed in contact, and the heater 3 is heated by passing a current through the electrodes.

A through-hole portion 3a enabling insertion of the rotation shaft 6 as described below is provided on approximately the center of the heater 3.

### [Heat Shield]

Next, the heat shield 4 will be described. The heat shield 4 is disposed on a lower side of the heater 3 as shown in FIG. 1. In other words, the heat shield 4 is disposed on the side opposite the CVD device wafer tray 2 with reference to the heater 3.

The heat shield 4 is disposed to prevent heat produced by the heater 3 from escaping downwardly.

In FIG. 1, although the heat shield 4 is configured in a double-layered configuration, there is no limitation in this respect, and a single layer, or three or more layers may be used. Furthermore, the heat shield 4 may be supported from below by a supporting column (not shown), or the lowermost layer of the heat shield 4 may be fixed and supported from below directly by a base 12 supported by a supporting column or the like.

Through holes 4a, 12a are respectively provided in approximately the center of the heat shield 4 and the base 12 to thereby enable insertion of the rotation shaft 6 as described below.

### [Heat Shield Ring]

Next, the heat shield ring 5 will be described. In FIG. 1, the heat shield ring 5 is disposed on a lower side of the CVD wafer tray 2, is provided to enclose the outer periphery of the heater 3 and the heater shield 4, and is configured in a cylindrical shape. The heat shield ring 5 is provided to prevent heat from the heater 3 from escaping sidewards.

As shown in FIG. 1, the heat shield ring 5 is disposed to cover the outer side of the distal end 11a of the flange 11 that is provided on the second surface 8b of the wafer tray main body 8. In addition, the heat shield ring 5 and the flange 11 are not in direct contact with each other, but are spaced apart from each other.

### [Rotation Shaft]

Next, the rotation shaft 6 will be described. The rotation shaft 6 is provided to rotate the wafer tray main body 8. A distal end 6a of the rotation shaft 6 is configured to be detachably connected to the connection indented portion 10 provided on the connection portion 9 of the wafer tray main body 8.

The shape of the distal end 6a of the rotation shaft 6 is formed as a circular truncated cone with a shape that corresponds to the connection indented portion 10 provided on the connection portion 9. The shape of the distal end 6a of the rotation shaft 6 is not limited to a circular truncated cone, and may take any shape as long as the shape corresponds to the shape of the connection indented portion 10.

The rotation shaft 6 is configured to enable insertion into the through-hole portion 3a provided on the heater 3, or the through holes 4a, 12a provided on the heat shield 4 and the base 12.

The rotation shaft 6 and the CVD device wafer tray 2 are connected by fitting the distal end 6a of the rotation shaft 6 into the connection indented portion 10, and not by fixing and connected by a special fixing means. In other words, the CVD device wafer tray 2 is supported on the rotation shaft 6 only by gravity.

The rotation shaft 6 is connected with a suitable means such as a motor or the like (not shown) on the opposite side to the distal end 6a, and is configured to be rotated by the motor. The rotation shaft 6 is configured to be cooled by an appropriate cooling means (not shown) such as water cooling.

Next, a method of forming a wafer thin film using the heating unit 1 for a CVD device according to the present invention will be described.

Firstly a CVD device wafer tray 2 that is not assembled into a CVD device heating unit 1 is prepared. Then, a desired wafer is mounted on the cavity 7 provided on the CVD device wafer tray 2. Thereafter, the CVD device wafer tray 2 is displaced by a suitable displacement means so that the distal end 6a of the rotation shaft 6 fits into the connection indented portion 10. The CVD device wafer tray 2 is rotated by the rotation shaft 6, and heated by the heater 3.

As described above, the wafer is heated to a reaction temperature and is brought into contact with a suitable reaction gas to thereby form a thin film.

### Second Embodiment

Next, a second embodiment of the present invention will be described. The present embodiment is a modification of the first embodiment and has the same configuration as the first embodiment with the exception that a portion of the CVD device wafer tray is different.

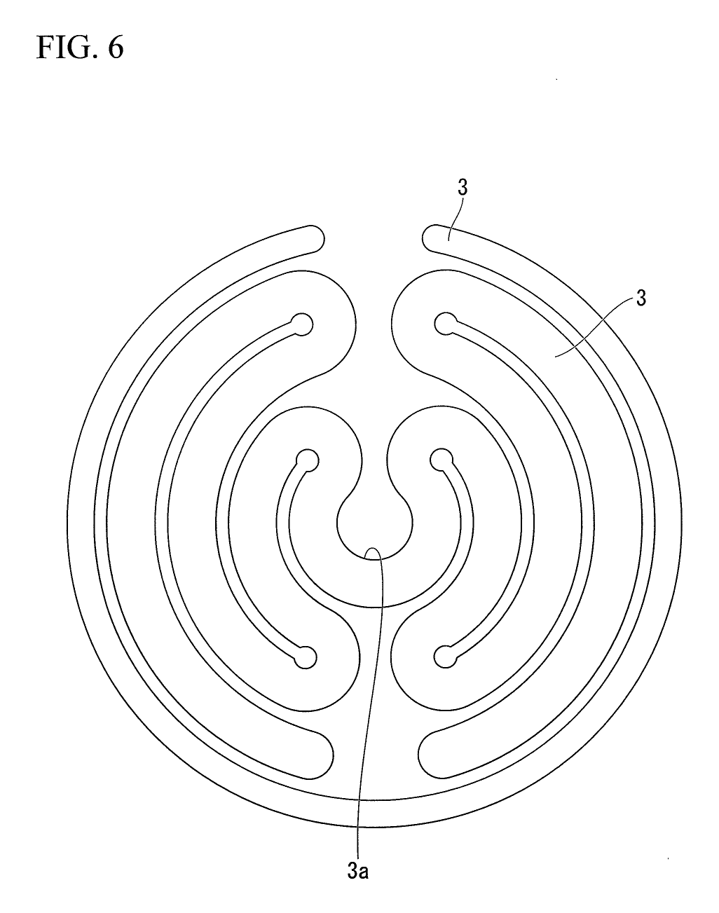

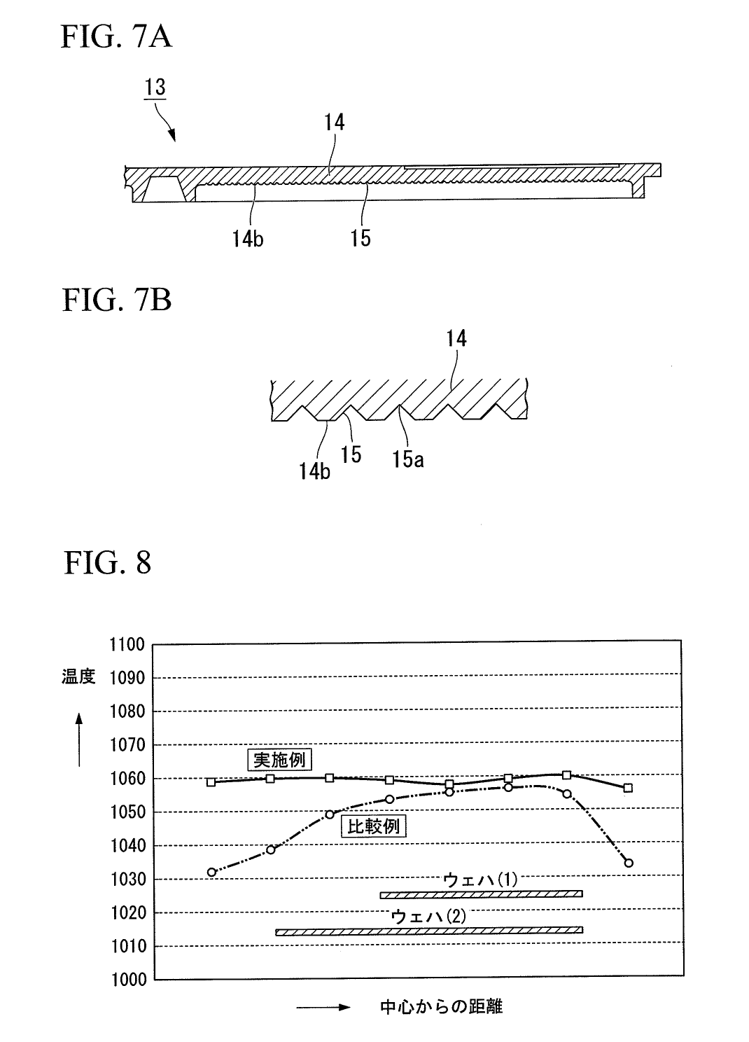

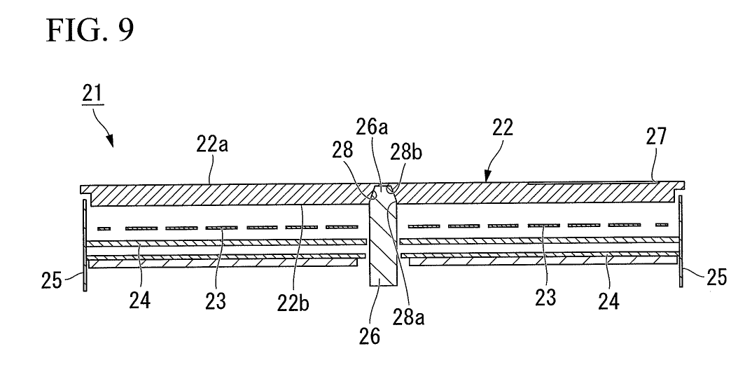

The CVD device wafer tray 13 according to the present embodiment differs from the first embodiment, and a plurality of indented portion or projecting portions 15 is formed across the entire or partial surface on the second surface 14b of the wafer tray main body 14. The indented portion or the projecting portion 15 is configured continuously or non-continuously. (In FIG. 7A and FIG. 7B, a continuous indented portion 15 includes a groove).

Since the indented portion or the projecting portion 15 is provided mainly for the object of increasing the surface area of the second surface 14b of the wafer tray main body 14, the indented portion or the projecting portion 15 may have any shape or depth as long as there is no adverse effect on the strength of the wafer tray main body 14. For example, when the indented portion has the structure of a groove 15, as shown in FIG. 7B, the deepest portion 15a of the groove 15 may be configured with an acute angle, or may be configured in a round configuration. The shape or pattern of the indented portion or the projecting portion as shown in other than FIG. 7B may have a disposition pattern having a concentric circular shape, radial shape, concentric polygonal shape, a lattice shape, or a spiral shape, and may have a sectional configuration in a triangular shape, or a polygonal shape, or a semicircular arc. For example, the configuration may be formed as described below. These patterns may be suitably combined.

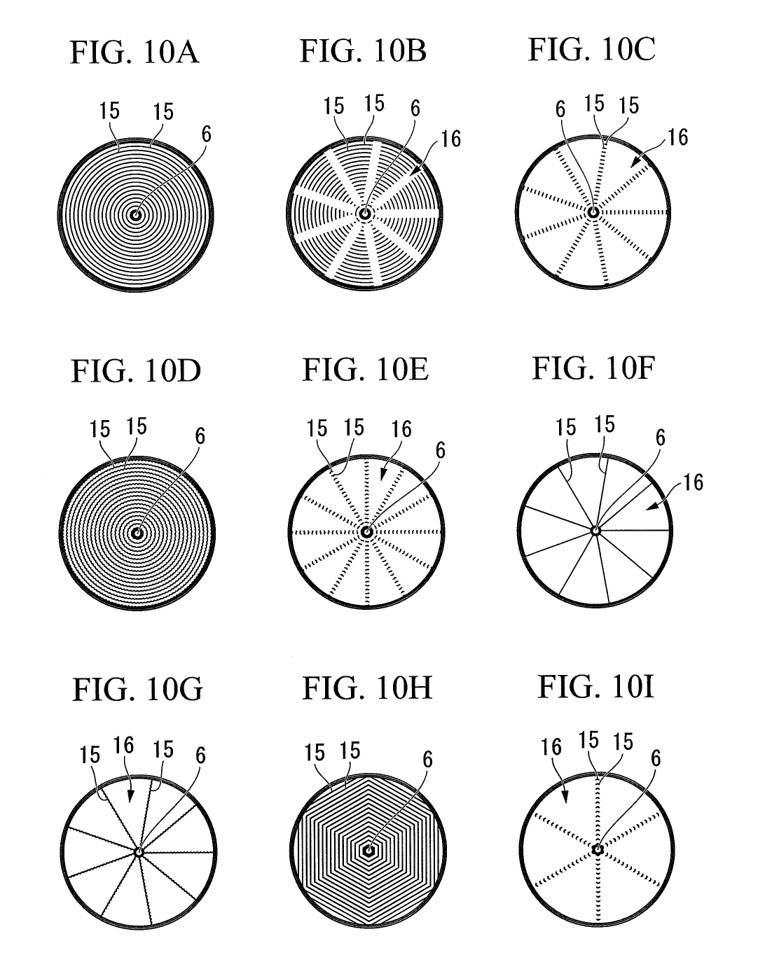

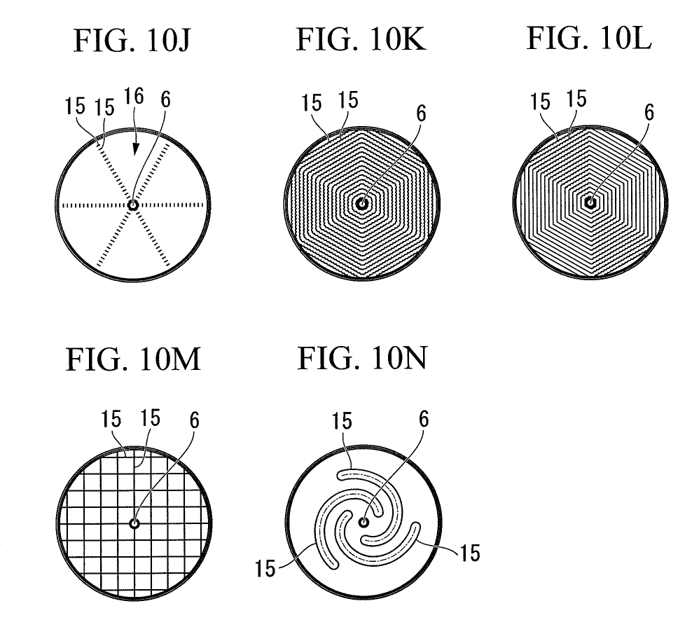

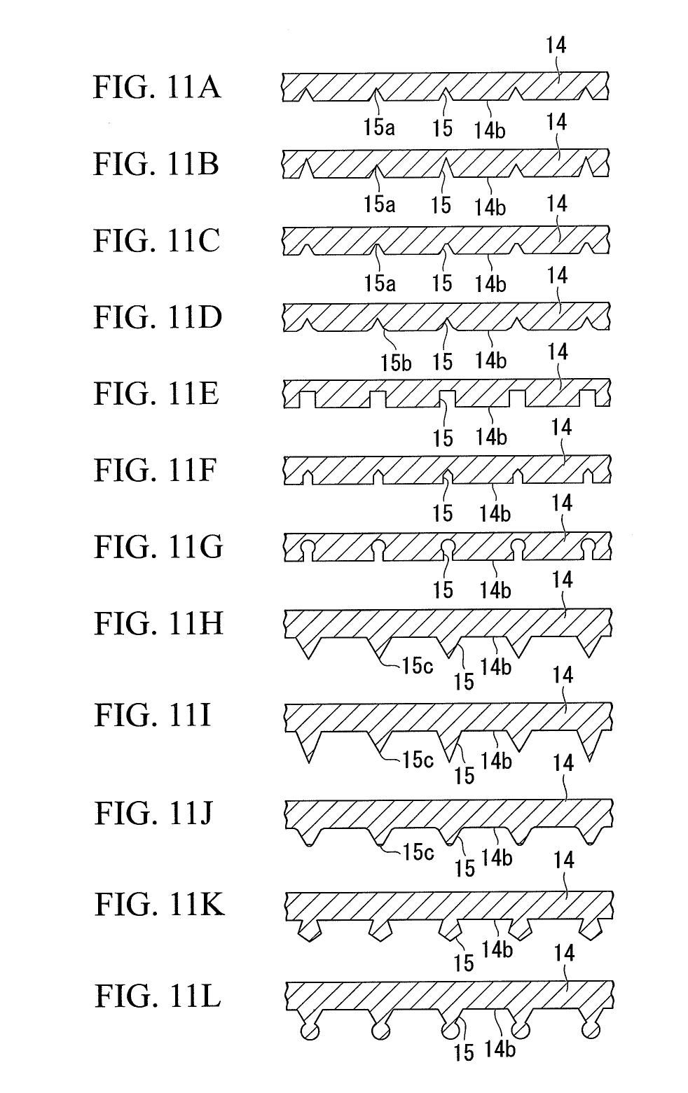

FIG. 10A-FIG. 10N are plan views showing examples of disposition patterns of the indented portion or the projecting portion 15 seen from the rear surface of the wafer rear main body 14. FIG. 11A-FIG. 11L illustrate sectional view showing examples of the sectional shape of the indented portion or the projecting portion 15.

FIG. 10A shows a pattern of disposing the plurality of indented portions or projecting portions 15 in a concentric configuration. FIG. 10B illustrates a pattern of disposition of a plurality of indented portions or projecting portions 15 in a concentric orientation in the same manner as FIG. 10A, and illustrates a pattern in which each indented portion or projecting portion 15 is separated by a non-configured portion 16 (A position at which the indented portion or projection portion is not formed. Hereinafter abbreviated to “non-configured portion 16”) that extends radially from the center of the wafer tray main body 14. FIG. 10C illustrates a pattern in which non-configured portion 16 shown in FIG. 10B is formed into concentric sectors.

FIG. 10D illustrates the same pattern as FIG. 10A of disposition of a plurality of indented portions or projecting portions 15 in a concentric orientation, and illustrates a pattern in which the indented portions or projecting portions 15 are configured in a meandering shape. FIG. 10E illustrates the same pattern as FIG. 10D of disposition of a plurality of indented portions or projecting portions 15 in a meandering shape, and illustrates a pattern in which each indented portion or projecting portion 15 is separated by a non-configured portion 16 that extends as concentric sectors.

FIG. 10F illustrates a pattern in which a plurality of indented portions or projecting portions 15 is disposed radially from the center of the wafer tray main body 14. FIG. 10G illustrates a pattern in which the indented portion or projecting portion 15 is disposed radially in the same manner as FIG. 10F, and shows a pattern in which the indented portion or projecting portion 15 has a meandering shape.

FIG. 10H illustrates a pattern in which a plurality of indented portions or projecting portions 15 is disposed in a concentric polygonal orientation. FIG. 10I illustrates a pattern in which the indented portion or projecting portion 15 is disposed only in proximity to the apex of each polygon in FIG. 10H, and other portions are configured as concentric non-configured portions 16. FIG. 10J illustrates a pattern in which the indented portion or projecting portion 15 is disposed at a position corresponding to a portion of each edge of each polygon in FIG. 10I.

FIG. 10K illustrates a pattern showing the same disposition as FIG. 10H, and in which the indented portion or projecting portion 15 has a meandering shape. FIG. 10L illustrates a pattern in which the indented portion or projecting portion 15 of a portion corresponding to an edge on a portion of each polygon in FIG. 10H has a meandering shape.

FIG. 10M illustrates a pattern in which a plurality of indented portions or projecting portions 15 is configured as a lattice. FIG. 10N illustrates a pattern in which a plurality of indented portions or projecting portions 15 is configured as a vortex.

However in the present invention, the indented portion or projecting portion 15 formed continuously or non-continuously is not limited to the shape shown in the plan view above.

Next, the sectional shape of the indented portion or projecting portion 15 will be described.

In all of FIG. 11A-FIG. 11D, the sectional shape of the indented portion 15 is triangular. In FIG. 11A, the deepest portion 15a of the indented portion is configured with an acute angle. In FIG. 11B, the deepest portion 15a of the indented portion is configured with an acute angle in the same manner as FIG. 11A, and indented portions 15 of different depths are alternately disposed from an inner side to an outer side. In FIG. 11C, the deepest portion 15a of a groove is configured with a curved surface. In FIG. 11D, the interface portion 15b between the indented portion 15 and the second surface 14b of the wafer tray main body 14 is configured with a curved surface.

FIG. 11E illustrates a pattern in which a sectional shape of the groove 15 is quadrilateral. FIG. 11F illustrates a pattern in which a sectional shape of the groove 15 is polygonal. FIG. 11G illustrates a pattern in which a bottom portion of the groove 15 in FIG. 11E forms a spherical recess.

In all of FIG. 11H-FIG. 11J, the sectional shape of the projecting portion 15 is triangular. In FIG. 11H, the apex 15c of the projecting portion 15 is configured with an acute angle. In FIG. 11I, projecting portions 15 of different sizes are alternately disposed. In FIG. 11J, the apex 15c of the projecting portion 15 is configured with a curved surface. In FIG. 11K, the sectional shape of the projecting portion 15 is polygonal. In FIG. 11L, a spherical protrusion is formed on a portion of the apex of the projecting portion 15.

In this manner, the depth of the indented portion or the height of the projecting portion in the sectional shape of the indented portion or projecting portion 15 as described above is preferably no more than 1 mm as a result of the restriction of the thickness l of the wafer tray main body 8. When the depth of the indented portion or the height of the projecting portion exceeds 1 mm, there is a risk that the mechanical strength of the wafer tray main body 8 is reduced.

In the present invention, the indented portion or projecting portion 15 formed continuously or non-continuously is not limited to the shape shown in the plan view above.

The pitch size of the indented portion or projecting portion 15 may be arbitrarily set without limitation thereon in the disposition pattern of the indented portion or projecting portion 15 as shown by example in FIG. 10A-FIG. 10N.

The CVD device wafer tray 13 according to the present embodiment forms the indented portion or projecting portion 15 on the second surface 14b of the wafer tray main body 14. In this manner, the surface area of the second surface 14b of the wafer tray main body 14 is increased, and heat from the heater 3 can be efficiently absorbed.

The CVD device wafer tray 13 may be configured by forming a protective layer on the surface of black lead, or a black-lead composite material. In this configuration, there is the risk of warping in the wafer tray main body 14 due to the difference in the coefficient of thermal expansion between black lead and the protective layer. When warping is produced, there is the risk that rotation of the CVD device wafer tray 13 will become unstable during rotation. Furthermore, there is the risk that a deviation in the shape of the cavity 7 formed on the wafer tray main body 14 will result.

As shown in this embodiment, the stress difference between the wafer tray main body 14 and the protective layer produced by the difference in the coefficient of thermal expansion can be mitigated by forming the indented portion or the projecting portion 15 on the rear surface of the wafer tray main body 13, and thereby prevent warping produced by the wafer tray main body 14.

A gaseous flow is produced under the wafer tray main body 14 as a result of the processing pressure during rotation of the CVD device wafer tray 13. This gaseous flow causes instability in the wafer tray main body 14, the wafer tray main body 14 itself inclines, and thereby a dynamic lift is produced. Consequently there is the risk the wafer tray main body 14 will undergo unstable motion, and separate from the rotation shaft 6. An aerodynamic effect is produced as a result of forming the indented portion or the projecting portion, and thereby it is possible to control the gaseous flow resulting from the variation in the processing pressure. Furthermore, a sharper variation in the processing pressure is enabled.

A desirable configuration in relation to a desirable gaseous flow includes a projecting portion that has a streamline sectional configuration exhibiting low resistance to a gaseous flow, or a small round shallow depression (dimple), or the like. These examples optimize the shape in relation to the gaseous flow due to the rotation direction and rotation speed of the tray.

As described above, the formation of the indented portion or the projecting portion 15 exhibits the three effects of thermal efficiency improvement, warping control in relation to materials, and aerodynamic control. However the indented portion or the projecting portion 15 may be separately disposed in the wafer tray main body 14 in order to independently obtain these effects. For example, the indented portion or the projecting portion may be formed on the surface of the wafer tray main body 14 to control warping of the material, the indented portion or the projecting portion may be formed on the rear surface of the wafer tray main body 14 to improve thermal efficiency, and the indented portion or the projecting portion may be formed on the side surface of the wafer tray main body 14 for aerodynamic control.

As described above, the present invention has been described based on the present embodiment. However the present invention is not limited to the above embodiments, and various modifications may of course be added within a scope that does not depart from the spirit of the invention.

### WORKING EXAMPLES

Although the working examples of the present invention are described below, the present invention is not limited by such working examples.

The CVD device heating unit used in the present working examples is a CVD device heating unit provided with the configuration shown in FIG. 1.

The CVD device wafer tray is configured from a wafer tray main body and a connection portion. The wafer tray main body is a disc-shaped component having a thickness of 7 mm, and a diameter of 460 mm when viewed in plan. A flange having a height of 8 mm is provided on the peripheral edge of the second surface of the wafer tray main body.

The connection portion is formed in a column shape with a height of 8 mm. The connection indented portion is formed in a bowl shape with a depth of 10.5 mm. Furthermore the thickness of the wafer tray main body in the connection indented portion is 4.5 mm.

The heater is separated by 20 mm below the CVD device wafer tray.

Five heat shields are disposed below the heater, and a 3 mm space is provided between the heater and the heat shield, and between each heat shield.

A base is provided below the heat shield that is disposed on the lower side. A heat shield ring is disposed on an outer side of the heater, the heater shield, and the flange provided on the second surface of the wafer tray main body. Furthermore the rotation shaft is connected to the connection indented portion.

The CVD device heating unit having the above configuration is used by application of a 30 kW power to the heater, and the temperature at respective distances from the center of a first surface of the wafer tray main body is measured. The results are shown in Table 1 and FIG. 8.

FIG. 8 shows the position of the wafer (1) (4 inch Φ) and the wafer (2) (6 inch Φ) in a range of respective distances from the center of the wafer tray main body provided with cavities. In other words, the region denoted as the wafer (1) is a region in which the distance from the center of the wafer tray main body is at least 130 mm and no more than 230 mm, and denotes a position in which the cavity is provided when forming the thin film on the wafer having a diameter of 100 mm (4 inch Φ). The region denoted as the wafer (2) is a region in which the distance from the center of the wafer tray main body is at least 80 mm and no more than 230 mm, and denotes a position in which the cavity is provided when forming the thin film on the wafer having a diameter of 150 mm (6 inch Φ).

In a comparative example, a conventional wafer tray is used in substitution for the CVD device wafer tray according to the working example. In other words, a wafer tray is used that is provided with an indented portion having a depth of 13.9 mm in substantially a central portion of the second surface and is formed in a disc shape having a diameter of 465 mm when viewed in plan at a depth of 15.9 mm. In addition, the same heater, the heat shield, the heat shield ring, and the rotation shaft as the working example is used. The results are shown in Table 1 and FIG. 8.

As shown in Table 1, in the working example, the temperature distribution becomes uniform irrespective of the distance from the center of the wafer tray main body. In contrast, in the comparative example, the temperature undergoes large fluctuation in response to the distance from the center of the wafer tray.

As clearly shown by FIG. 8, when intending to form a thin film with a CVD method, the CVD device wafer tray according to the comparative example, and in particular when forming a film by use of a 150 mm (6 inch Φ) diameter wafer, a large temperature difference results from the position in the wafer. Consequently, there is a risk of quality defects. In contrast, the CVD device wafer tray according to the working example does not exhibit a temperature difference, and enables stable manufacture of a superior thin film product.

TABLE 1

| Distance from Center | Working Example | Comparative Example |
|---|---|---|
| 22 | 1059 | 1032 |
| 44 | 1060 | 1039 |
| 67 | 1060 | 1049 |
| 89 | 1059 | 1053 |
| 112 | 1058 | 1055 |
| 134 | 1059 | 1057 |
| 156 | 1060 | 1054 |
| 179 | 1056 | 1034 |

### DESCRIPTION OF THE NUMERALS

1 CVD DEVICE HEATING UNIT
2 CVD DEVICE WAFER TRAY
3 HEATER
4 HEAT SHIELD
5 HEAT SHIELD RING
6 ROTATION SHAFT
7 CAVITY
8 WAFER TRAY MAIN BODY
8a FIRST SURFACE OF WAFER TRAY MAIN BODY
8b SECOND SURFACE OF WAFER TRAY MAIN BODY
8d PERIPHERAL EDGE OF SECOND FACE OF WAFER TRAY MAIN BODY
9 CONNECTION PORTION
10 CONNECTION INDENTED PORTION
11 FLANGE
15 INDENTED PORTION OR PROJECTING PORTION
16 NON-CONFIGURED PORTION
l THICKNESS OF WAFER TRAY MAIN BODY
m DEPTH OF CONNECTION INDENTED PORTION
p THICKNESS OF WAFER TRAY MAIN BODY AT CONNECTION INDENTED PORTION

1. A wafer tray for a CVD device comprising a wafer tray main body provided with cavities enabling mounting of a wafer on a first surface, and a connection portion formed to project towards a second surface of the wafer tray main body, wherein a connection indented portion is provided in the connection portion to enable detachable connection to the rotation shaft that enables rotation of the wafer tray main body.

2. The wafer tray for a CVD device according to claim 1 wherein the thickness of the wafer tray main body in a portion not provided with the connection portion is less than the depth of the connection indented portion.

3. The wafer tray for a CVD device according to claim 1 wherein the thickness of the wafer tray main body in the connection indented portion is at least 50% of the thickness of the wafer tray main body in the portion not provided with the connection portion.

4. The wafer tray for a CVD device according to claim 1 wherein the thickness of the wafer tray main body in the connection indented portion is at least 3 mm.

5. The wafer tray for a CVD device according to claim 1 wherein a flange is provided on the peripheral edge of the second surface of the wafer tray main body.

6. The wafer tray for a CVD device according to claim 1 wherein an indented portion or projecting portion is provided on the second surface of the wafer tray main body.

7. The wafer tray for a CVD device according to claim 6 wherein the indented portion or the projecting portion is configured in a concentric circular shape, radial shape, concentric polygonal shape, a lattice shape, or a spiral shape.

8. The wafer tray for a CVD device according to claim 6 wherein the indented portion or the projecting portion is configured continuously or non-continuously.

9. The wafer tray for a CVD device according to claim 6 wherein the sectional shape of the indented portion or the projecting portion includes at least one shape selected from the group consisting of a triangular shape, a polygonal shape, or a semicircular shape.

10. A CVD device heating unit comprising the wafer tray according to claim 1, a heater that heats the CVD device wafer tray from the second surface side of the wafer tray main body, a heat shield that is disposed on the opposite side to the wafer tray main body with reference to the heater, a heat shield ring that encloses the outer periphery of the heater, and a rotation shaft that enables the wafer tray main body to rotate.

11. A CVD device comprising the CVD device wafer tray according to claim 1.
